(19) United States
(12) Patent Application Publication
(10) Pub. No.: US 2026/0146323 A1
(43) Pub. Date: May 28, 2026

(54) ION TRAPS WITH SLANTED HOLES IN SUBSTRATE PROCESSING SYSTEMS

(71) Applicant: ASM IP HOLDING B.V., Almere (NL)

(72) Inventor: Tommi Tynell, Espoo (FI)

(21) Appl. No.: 19/360,506

(22) Filed: Oct. 16, 2025

Related U.S. Application Data
(60) Provisional application No. 63/709,050, filed on Oct. 18, 2024.

(51) Int. Cl. C23C 16/455; H01J 37/30; H01J 37/317

(52) U.S. Cl. CPC C23C 16/45544; C23C 16/45536; H01J 37/3007; H01J 37/3178

(57) ABSTRACT

Ion traps for use in substrate processing systems are disclosed. The ion traps may comprise at least one hole. The hole may comprise an interior surface that is slanted relative to a top surface or a bottom surface of the ion trap. The hole may prevent plasma ions from passing through the ion trap and/or allow plasma radicals to pass through the ion trap.

### CROSS-REFERENCE TO RELATED APPLICATION(S)

This Application claims the benefit of U.S. Provisional Application 63/709,050 filed on Oct. 18, 2024, the entire contents of which are incorporated herein by reference.

### FIELD OF INVENTION

The present disclosure relates to a substrate processing system, more particularly to an ion trap of a substrate processing system performing radical-enhanced atomic layer deposition.

### BACKGROUND OF THE DISCLOSURE

Atomic layer deposition (ALD) is a method of depositing a thin film on the surface of a substrate by exposing the substrate to two or more vapor-phase chemical reactants or precursors. ALD may provide for uniform and conformal coverage of the substrate and precise control over the film thickness. However, the ALD process may be generally slow and/or highly dependent on the temperature in the reaction chamber and/or of the substrate. If the substrate or chamber temperature is too high, desorption of the chemisorbed layer may occur. If the temperature is too low, the deposition reaction may be too slow and the reaction may not proceed to completion or not at all, leading to poor film quality. Thus, the narrow temperature window may limit the number of suitable precursors in traditional thermal ALD processes.

Plasma-enhanced ALD (PE-ALD) may be used to overcome some of the limitations of thermal ALD processes. PE-ALD may use radical species, generated by exposing precursors to plasma, as reactants in the ALD process. The use of energetic radicals as reactants may increase the reactivity on the surface of the substrate, allow for lower temperature processing, allow for a wider selection of precursors with higher thermal and chemical stabilities, and, in many instances, provide improved film properties (e.g., density, impurity level, and electronic properties).

Various reactor configurations may be employed to influence the types and density of the plasma species that interact with the substrate. In direct PE-ALD, precursors may be exposed to plasma in close proximity to the substrate surface to form energetic radicals, ions, etc. The flux of energetic radicals in close proximity to the substrate can be high, allowing for uniform film formation and short plasma exposure times, but plasma-induced damage and anisotropy in the film can also occur because of exposure of the surface of the substrate to the ions. In remote PE-ALD, the plasma may be located further away from the substrate surface, reducing, but not eliminating, the flux of ions to the substrate surface. In contrast, in radical-enhanced ALD (RE-ALD), which is another type of PE-ALD, ions may be prevented from reaching the substrate surface. This RE-ALD approach may avoid the plasma-induced damage and anisotropy often associated with PE-ALD processes while still providing an advantage in reactivity over thermal ALD processing.

Ions may be prevented from reaching the substrate surface in RE-ALD by providing an electrically grounded ion trap between the substrate and the reaction space where plasma is provided. Such ions traps may comprise holes that let radical species pass onto the substrate surface while trapping the ions. However, the holes in the ion traps may not trap all the ions, and some of the ions may pass through the ion trap and counteract some of the benefits of RE-ALD. Additionally, the holes in the ion traps may provide a large surface area for the radicals to combine with the trapped ions, thereby reducing the number of radicals passing through the ion trap and contacting the substrate surface. Therefore, ion trap designs that allow increased efficiencies of trapping ions and decrease the possibility of radicals combining with the ions while the radicals pass through the ion trap may be desirable.

Any discussion, including discussion of problems and solutions, set forth in this section has been included in this disclosure solely for the purpose of providing a context for the present disclosure. Such discussion should not be taken as an admission that any of the information was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

The reactor system disclosed herein may comprise ion traps that facilitate increased efficiencies in trapping ions and/or decrease the possibility of radicals combining on the surfaces of the ion traps while the radicals are passing through the ion traps. The reactor system described herein may comprise a susceptor configured to support a substrate, a precursor distribution system positioned above the susceptor and configured to provide one or more precursors into the reaction chamber of the reactor system, a radio frequency (RF) power source configured to supply RF power for generating, in the reaction chamber, ions and radicals from the one or more precursors, and an ion trap positioned between the susceptor and the precursor distribution system. The ion trap may comprise at least one hole, and the at least one hole may comprise an interior surface that is slanted relative to a top surface or a bottom surface of the ion trap. The slanted interior surface may be configured to prevent the ions from passing through the ion trap and contacting the substrate and/or to allow the radicals to pass through the ion trap.

In various embodiments, the interior surface of the hole may create an angle in a range of 70 to 85 degrees with the top surface or the bottom surface of the ion trap.

In various embodiments, the hole may comprise an opening on the top surface or the bottom surface of the ion trap, and/or the opening may comprise a circular shape with a diameter in a range of 0.1 to 5 millimeters. In various embodiments, the hole may be shaped as an oblique cylinder, and the oblique cylinder may comprise an aspect ratio in a range of 1 to 400. In various embodiments, the hole may comprise an opening on the top surface or the bottom surface of the ion trap, where the opening may comprise a circular shape, a square shape, a rectangular shape, or a parallelogram shape.

In various embodiments, the opening may comprise a rectangular shape with a width in a range of 0.1 to 5 millimeters. In various embodiments, the opening may comprise a spiral shape with a width in a range of 0.1 to 5 millimeters. In various embodiments, the ion trap may have a thickness in the range of 5 to 40 millimeters.

In various embodiments, the ion trap may comprise a plurality of holes with interior surfaces slanted relative to the top surface or the bottom surface of the ion trap, and the plurality of holes may be parallel to each other.

In various embodiments, the reactor system may further comprise a power source electrically connected to at least one of the susceptor and the precursor distribution system and/or a controller configured to enable the ions and the radicals to move vertically toward the susceptor by activating the power source to apply a voltage bias across the susceptor and the precursor distribution system. In various embodiments, the ion trap may be connected to a ground connection.

Described herein is a ion trap of a reaction chamber, where the ion trap may comprise a plurality of holes. The interior surface, of each of the plurality of holes, may be slanted relative to a top surface or a bottom surface of the ion trap. The plurality of holes may be configured to block ions from passing through the ion trap and/or allow radicals to pass through the ion trap. The interior surface of each of the plurality of holes may create an angle in a range of 70 to 85 degrees with the top surface or the bottom surface of the ion trap.

In various embodiments, each of the plurality of holes may comprise a shape of an oblique cylinder with a diameter in a range of 0.1 to 5 millimeters and/or an aspect ratio in a range of 1 to 400. In various embodiments, each of the plurality of holes may comprise a cross-section of a rectangular shape with a width in a range of 0.1 to 5 millimeters. In various embodiments, the plurality of holes may be parallel to each other. In various embodiments, the ion trap may have a thickness in the range of 5 to 40 millimeters.

Described herein is another ion trap of a reaction chamber, where the ion trap may comprise a hole comprising a spiral-shaped cross-section. The interior surface of the spiral-shaped hole may be slanted relative to a top surface or a bottom surface of the ion trap. The spiral-shaped hole may be configured to block ions from passing through the ion trap and/or allow radicals to pass through the ion trap.

For the purpose of summarizing the disclosure and the advantages achieved over the prior art, certain objects and advantages of the disclosure have been described herein above. Of course, it is to be understood that not necessarily all such objects or advantages may be achieved in accordance with any particular embodiment of the disclosure. Thus, for example, those skilled in the art will recognize that the embodiments disclosed herein may be carried out in a manner that achieves or optimizes one advantage or group of advantages as taught or suggested herein without necessarily achieving other objects or advantages as may be taught or suggested herein.

All of these embodiments are intended to be within the scope of the disclosure. These and other embodiments will become readily apparent to those skilled in the art from the following detailed description of certain embodiments having reference to the attached figures, the disclosure not being limited to any particular embodiment(s) discussed.

### BRIEF DESCRIPTION OF THE DRAWING FIGURES

While the specification concludes with claims particularly pointing out and distinctly claiming what are regarded as embodiments of the disclosure, the advantages of embodiments of the disclosure may be more readily ascertained from the description of certain examples of the embodiments of the disclosure when read in conjunction with the accompanying drawings. Elements with the like element numbering throughout the figures are intended to be the same.

FIG. 1 is a schematic diagram of an exemplary reactor system in accordance with various embodiments.

FIGS. 2A, 2B, and 2C illustrate an exemplary ion trap of a reactor system in accordance with various embodiments.

FIGS. 3A, 3B, and 3C illustrate an exemplary ion trap with slanted holes in accordance with various embodiments.

FIGS. 4A, 4B, and 4C illustrate exemplary ion traps with holes of rectangular cross-sections in accordance with various embodiments.

FIGS. 5A, 5B, and 5C illustrate exemplary ion traps with a spiral hole in accordance with various embodiments.

FIG. 6 is a process diagram of an exemplary embodiment of the disclosure.

The accompanying drawings are incorporated into and form a part of the specification to illustrate several examples of the present disclosure. The figures presented herein are not meant to be actual views of any particular material, structure, or device, but are merely idealized representations that are used to describe embodiments of the disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The drawings, together with the description, explain the principles of the disclosure. The drawings may simply illustrate preferred and alternative examples of how the disclosure can be made and used and are not to be construed as limiting the disclosure to only the illustrated and described examples. Further features and advantages will become apparent from the following, more detailed, description of various aspects, embodiments, and configurations of the disclosure, as illustrated by the drawings referenced below.

### DETAILED DESCRIPTION OF EXEMPLARY EMBODIMENTS

Although certain embodiments and examples are disclosed below, it will be understood by those in the art that the invention may extend beyond the specifically disclosed embodiments and/or use of the invention and obvious modifications and equivalents thereof. Thus, it is intended that the scope of the invention disclosed should not be limited by the particular disclosed embodiments described below.

The illustrations presented herein are not meant to be actual views of any particular material, apparatus, structure, or device, but are merely representations that are used to describe embodiments of the disclosure.

As used herein, the term “substrate” may refer to any underlying material or materials, including any underlying material or materials that may be modified, or upon which, a device, a circuit, or a film may be formed.

As used herein, the term “atomic layer deposition” (ALD) may refer to a vapor deposition process in which deposition cycles, preferably a plurality of consecutive deposition cycles, are conducted in a process chamber. Typically, during each cycle, the precursor is chemisorbed to a deposition surface (e.g., a substrate surface or a previously deposited underlying surface such as material from a previous ALD cycle), forming a monolayer or sub-monolayer that does not readily react with additional precursor (e.g., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as “chemical vapor atomic layer deposition,” “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) may refer to any process wherein a substrate is exposed to one or more volatile precursors, which react and/or decompose on a substrate surface to produce a desired deposition.

As used herein, the terms “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise a material or a layer with pinholes, but still be at least partially continuous.

As used herein, “chemisorption” may refer to an absorption process caused by a reaction on an exposed surface, which creates, for example, a covalent or ionic bond between the surface and the adsorbate.

As used herein, a “gas” may refer to a state of matter consisting of atoms or molecules that have neither a defined volume nor shape. A gas may include a vaporized solid and/or liquid and may be constituted by a single gas or a mixture of gases, depending on the context.

As used herein, a “plasma” may refer to an ionized gas comprising roughly equal numbers of negatively and positively charged species, generally electrons and ions. Excited and reactive species may also be contained within the plasma, such as, for example, atoms and radicals, metastable atoms and molecules, and photons. A plasma discharge requires an externally imposed electric or magnetic field to ionize a gas. Plasma generation schemes and geometries, may include, but are not limited to, capacitively coupled plasmas (CCPs), inductively coupled plasmas (ICPs), and RF-hollow cathode (HC) plasmas, which differ in their production of excited and reactive species and, as a result, they can provide very different fluxes of the various species.

As used herein, a “precursor” may refer to a compound that participates in a chemical reaction to form another compound or element, wherein a portion of the precursor (an element or group within the precursor) may be incorporated into the compound or element that results from the chemical reaction. The compound or element that results from the chemical reaction may be a layer and/or a film that is formed on a surface of a substrate.

As used herein, a “reactant” refers to a compound that participates in a chemical reaction to form another compound or element. In some instances, a reactant may be a precursor. In other instances, the compound or element that results from the chemical reaction does not contain a portion of the reactant (an element or group within the reactant), and therefore the reactant is not a precursor.

It should be understood that every numerical range given throughout this disclosure may be deemed to include the upper and the lower endpoints and each and every narrower numerical range that falls within such broader numerical range, as if such narrower numerical ranges were all expressly written herein. By way of example, the phrase “from about 2 to about 4” or “from 2 to 4” includes 2 and 4, and the whole number and/or integer ranges from about 2 to about 3, from about 3 to about 4 and each possible range based on real (e.g., irrational and/or rational) numbers, such as from about 2.1 to about 3.9, from about 2.1 to about 3.4, and so on.

The present disclosure generally relates to systems for forming a film on the surface of a substrate using plasma-enhanced atomic-layer deposition (PE-ALD), remote PE-ALD, and/or radical-enhanced ALD (RE-ALD), and in particular with the use of plasma to affect the partial breakdown of chemical precursors to enhance their reactivity.

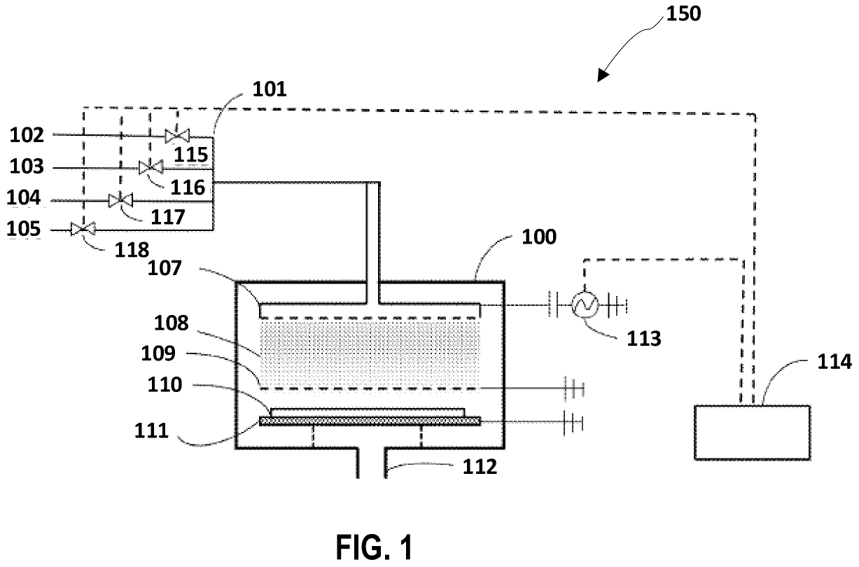

Reactor systems used for ALD, CVD, PE-ALD, remote PE-ALD, RE-ALD, and/or the like, may be used for a variety of applications, including depositing and etching materials on a substrate surface. FIG. 1 illustrates an example reactor system 150 where plasma may be formed in the upper portion of the reaction chamber 100, such as the plasma zone 108. A first vapor-phase or gas-phase precursor may be supplied from a first precursor source 102, a second vapor-phase precursor may be supplied from a second precursor source 103, a third vapor-phase precursor may be supplied from a third precursor source 104, and/or a fourth vapor-phase precursor may be supplied from a fourth precursor source 105. The vapor-phase precursors from the first precursor source 102, the second precursor source 103, the third precursor source 104, and/or the fourth precursor source 105 may be provided into the reaction chamber 100 through a manifold 101. The manifold 101 may comprise a first valve 115 that controls the flow of the first vapor-phase precursor from the first precursor source 102, a second valve 116 that controls the flow of the second vapor-phase precursor from the second precursor source 103, a third valve 117 that controls the flow of the third vapor-phase precursor from the third precursor source 104, and/or a fourth valve 118 that controls the flow of the fourth vapor-phase precursor from the fourth precursor source 105. The precursor may flow into the reaction chamber 100 through a precursor distribution system 107 that may be positioned directly above a susceptor 111 on which a substrate 110 (i.e., wafer, a planar substrate) is placed. The first precursor may be vaporized and entrained in or pulsed into a carrier gas. The reactor system 150 may also be configured to allow for the introduction of other gases, such as the reactive gas and other gases (e.g., other precursors or reactive gasses, carrier, dilutant, process, feed, carrier gas, and/or purging gasses), either through the precursor distribution system 107 or from other ports (not shown) into the reaction chamber.

Unreacted gasses and gaseous reaction byproducts may exit the reaction chamber 100 through an exhaust line 112. The reaction chamber 100 may optionally be equipped with a purge line and/or a pump line coupled to a vacuum pump so that the reaction chamber may be purged between the various reaction cycles (not shown).

An RF power source 113 may be electrically connected to the precursor distribution system 107, allowing for the precursor distribution system to be biased relative to the susceptor 111 to form a plasma discharge between the two. The applied bias may allow the ions and radicals to accelerate downward toward the substrate 110/susceptor 111. A ion trap 109 (e.g., a mesh plate) may be positioned between the precursor distribution system 107 and the substrate 110/susceptor 111 to restrict the plasma zone 108 to the upper portion of the reaction chamber 100 above the ion trap 109. The ion trap may be electrically grounded or may be connected to a ground connection. In some embodiments, the ion trap may be a metal plate comprising one or more holes that let radical species pass through to the substrate 110 while trapping the ions. The addition of the ion trap 109 may reduce or even eliminate interactions of electrons and ions with the surface of the substrate 110 by restricting the plasma to the plasma zone 108 in the upper portion of the reaction chamber 100 and/or the ion trap absorbing the ions trying to flow toward the surface of the substrate 110.

The reactor system 150 may also comprise a controller 114 operably connected to the first, second, third, and fourth gas valves, 115-118, the RF power source 113, and other components (not shown). The controller 114 may be configured and programmed to independently control (e.g., turn on and off, etc.) the supply of the various gasses (e.g., carrier gas, first precursor, reactive gas, and any dilutant, process, feed, and/or purging gasses etc.) and the RF power source 113, as required, to deposit a film on the surface of the substrate 110. In some embodiments, the controller 114 may be configured to open valve 115 to flow the first vapor-phase precursor from the first precursor source 102 into the reaction chamber 100. The controller 114 may be further configured to turn on the RF power source 113 to form plasma (e.g., low-power plasma). Turning on the RF power source 113 and opening valve 115 may be done one after the other, or simultaneously. After a set period of time, the controller 114 may close the valve 115 and turn off the RF power source 113. Next, the controller 114 may open valve 116 to flow a second vapor-phase precursor from the second precursor source 103 into the reaction chamber 100. After a set period of time, the controller 114 may close the valve 116. The controller 114 may be programmed to repeat the various process steps to grow a film on the surface of the substrate 110. The controller 114 may be programmed to perform other process steps in between these various steps.

In another embodiment, the controller 114 may be configured to open valve 115 to flow the first precursor from the first precursor source 102 into the reaction chamber, then open valve 116 to flow the second precursor from the second precursor source 103 into the reaction chamber while turning on the RF power source 113 to form plasma. Turning on the RF power source 113 and opening valves 115 and 116 may be done one after the other, or simultaneously. After a set period of time, the controller 114 may close the valve 115 and the valve 116 and turn off the RF power source 113. Next, the controller 114 opens the valve 117 to flow the third precursor from the third precursor source 104 into the reaction chamber 100 and, after a set period of time, pulses (turn on, then off) the RF power source 113. After another set period of time, the controller 114 may close the valve 117. The controller 114 may be programmed to repeat the various process steps to grow a film on the surface of the substrate 110. The controller 114 may be programmed to perform other process steps in between these various steps.

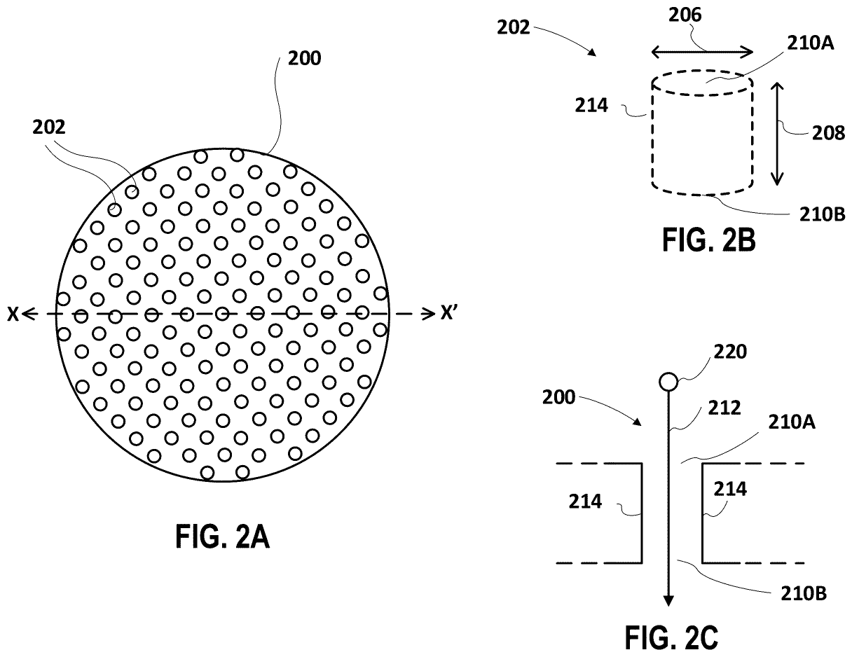

FIG. 2A illustrates an example ion trap 200 that may be provided in the reactor system 150. The ion trap 200 may comprise multiple holes 202. While a limited number of holes are shown in the ion trap 200, the ion trap 200 may comprise hundreds or thousands of holes 202 in a showerhead-like pattern. The holes 202 may be shaped as a cylinder, as illustrated in the outline of an example hole 202 in FIG. 2B. For example, the interior surface 214 of the hole 202 may be perpendicular (e.g., not slanted) to the top surface of the ion trap 200 or the bottom surface of the ion trap 200. The hole may have a top opening 210A on the top surface of the ion trap 200 and/or a bottom opening 210B on the bottom surface of the ion trap 200. The top opening 210A and the bottom opening 210B may be circular shaped, having a diameter 206 between about 0.1 millimeter to about 5 millimeters. The height 208 of the hole 202 (also the thickness of the ion trap 200) may be between about 5 millimeters to about 40 millimeters. Therefore, the aspect ratio of the hole 202 may be between 1 and 400.

FIG. 2C illustrates a cross-sectional view of the ion trap 200 along the x-x′ axis. The hole 202 may let any radicals flowing toward the substrate (e.g., substrate 110) pass through the ion trap 200 by allowing the radicals to enter via the top opening 210A on the top surface of the ion trap 200 and exiting via the bottom opening 210B on the bottom surface of the ion trap. The holes 202 may trap some ions flowing toward the substrate. Usually, a high aspect ratio of the holes 202 of the ion trap 200 in the order of 1-400 may effectively capture or trap the ions. However, the cylindrical shape of the holes 202 does not trap all ions, and some of the ions may exit via the bottom opening 210B on the bottom surface of the ion trap. For example, as illustrated in FIG. 2C, an ion 220 may be flowing toward a substrate in a perpendicular direction 212 and enter the ion trap 200 through the top opening 210A of the upper surface of the ion trap 200 and exit through the bottom opening 210B of the bottom surface of the ion trap 200. Thus, ion traps 200 with cylindrical holes may run the risk of having some ions contacting the surface of the substrate, causing plasma-induced damage and anisotropy in the thin film formed on the surface of the substrate.

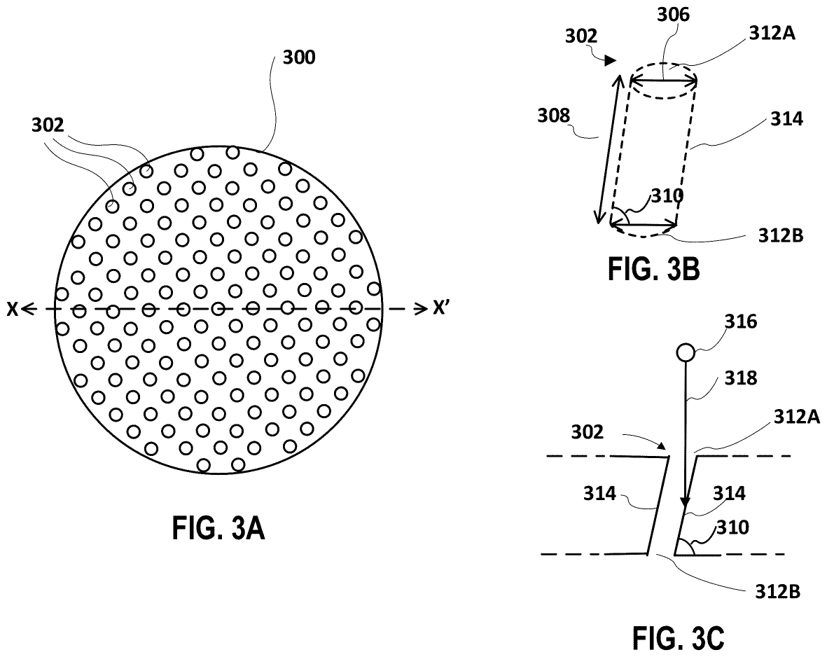

Another example of a ion trap 300 is provided in FIGS. 3A, 3B, and 3C, and the ion trap 300 may have a higher efficiency in trapping ions when compared to the ion trap 200 in FIG. 2A. The ion trap 300 may be provided in the reactor system 150 (e.g., as the ion trap 109). The ion trap 300 may comprise multiple slanted holes 302. While a limited number of slanted holes are shown in the ion trap 300, the ion trap 300 may comprise hundreds or thousands of slanted holes 302. The slanted holes 302 may be shaped as an oblique cylinder, as illustrated in the outline of an example slanted hole 302 in FIG. 3B. For example, the interior surface 314 of the hole 302 may be slanted (e.g., not perpendicular) to the top surface of the ion trap 300 or the bottom surface of the ion trap 300. For example, the interior surface 314 of the slanted hole 302 may create an angle 310 in a range of 45 to 89 degrees with the top surface or the bottom surface of the ion trap. In some examples, the angle 310 may be in the range of 70 to 85 degrees.

As illustrated in FIGS. 3B and 3C, the slanted hole 302 may have a top opening 312A on the top surface of the ion trap 300 and/or a bottom opening 312B on the bottom surface of the ion trap 300. The top opening 312A and the bottom opening 312B may be circular shaped, having a diameter 306 between about 0.1 millimeter to about 5 millimeters. Alternatively, in other embodiments, the top opening 312A and/or the bottom opening 312B may comprise a square shape, a rectangular shape, a parallelogram shape, or any two-dimensional shape. The height 308 of the slanted hole 302 may be between 5 millimeters to about 40 millimeters. Therefore, the aspect ratio of the slanted hole 302 (e.g., the height 308 divided by the diameter 306) may be between 1 and 400. The height 308 of the slanted hole 302 may be greater than the thickness of the ion trap 300.

While the ion trap 200 of FIGS. 2A-C may be manufactured by drilling holes perpendicular to the top or bottom surface of the ion trap 200, the ion trap 300 of FIGS. 3A-3C may be manufactured by drilling the holes at an angle (e.g., angle 310) to the top or bottom surface of the ion trap, resulting in the slanted holes 302. Apart from the different hole designs for the ion trap, there may be no other changes to the reactor system 150 and/or the method of running the reactor system 150 to process substrates.

FIG. 3C illustrates a cross-sectional view of the ion trap 300 along the x-x′ axis. The slanted holes 302 may let any radical species flowing toward the substrate (e.g., substrate 110) pass through the ion trap 300 by allowing the radicals to enter via the top opening 312A on the top surface of the ion trap 300 and exiting via the bottom opening 312B on the bottom surface of the ion trap 300. However, the slanted interior surface 314 may trap ions flowing toward the substrate. For example, as illustrated in FIG. 3C, an ion 316 may be flowing toward a substrate in a perpendicular direction 318 and enter the ion trap 300 through the top opening 312A of the upper surface of the ion trap 300. After entering the slanted hole 302, the ion 316 may collide with the slanted interior surface 314 and/or get absorbed by the slanted interior surface 314.

The ion trap 300 with slanted holes 302 may have improved the trapping of ions when compared to the ion trap 200 and may enable the complete removal of ions from the plasma flux, ensuring that only reactive radicals can reach the substrate. Thus, the ion trap 300 with slanted holes 302 may enhance REALD processes by reducing the risks of any unintended etching, densification, or anisotropy effects arising from ion bombardments on the surface of the substrate 110.

The ion trap 200 with non-slanted holes 202 and/or the ion trap 300 with slanted holes 302 may not allow enough radicals to pass through for efficient REALD processing. This may be because the ion trap 200 may have hundreds or thousands of non-slanted holes 202 with a high aspect ratio (e.g., aspect ratio higher than 10) and/or the ion trap 300 may have hundreds or thousands of slanted holes 302 with a high aspect ratio (e.g., aspect ratio higher than 10). Such holes with high aspect ratios may have a large amount of interior surface areas (e.g., a sum of all the interior surface areas 214 of the holes 202 or a sum of the interior surface areas 314 of the slanted holes 302), which may hinder the delivery of radicals to the substrate as the large amount of interior surface areas may provide more surface areas where radicals can react or recombine with other radicals, ions or dangling bonds on the surface, thereby reducing the amount of radical flow through the ion traps.

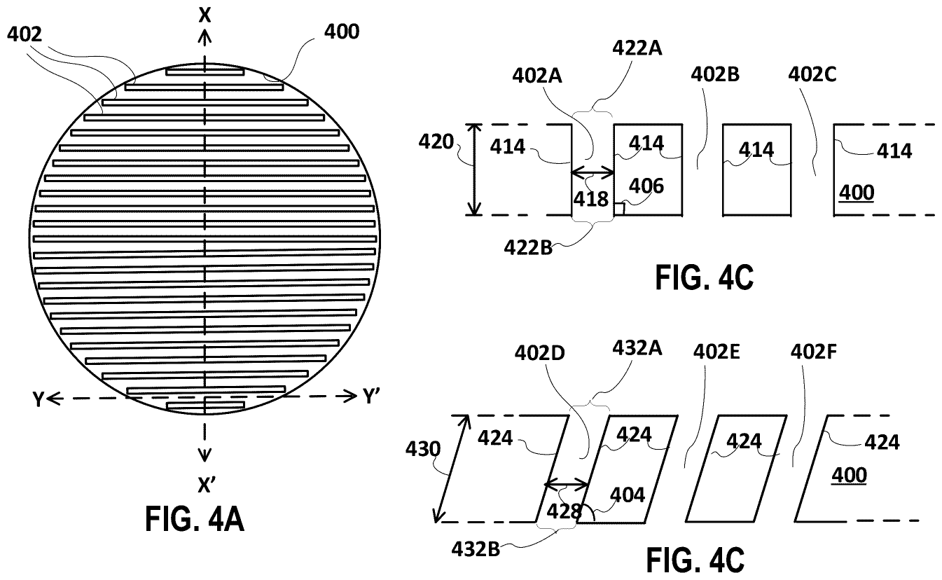

The interior surface areas of the ion traps may be reduced by enlarging the holes. For example, FIG. 4A illustrates an example ion trap 400 with elongated holes 402 (e.g., slits in the ion trap 400). The cross-section of the elongated holes 402 may be rectangular with 90-degree corners. Alternately, the cross-section of the elongated holes 402 may be rectangular with rounded corners, trapezoidal, or other similar two-dimensional shapes. The lengths of elongated holes 402 (e.g., lengths along the y-y′ axis) may be parallel to each other and may span from one edge of the ion trap 400 to another end of the ion trap 400.

The elongated holes 402 may be non-slanted or slanted. For example, FIG. 4B illustrates a cross-sectional view of the ion trap 400 with non-slanted elongated holes 402A, 402B, and 402C along the x-x′ axis. The interior surfaces 414 of the non-slanted elongated holes 402A-C may be perpendicular to the top surface of the ion trap 400 or the bottom surface of the ion trap 400. The angle 406 between the interior surfaces 414 and the top or bottom surface may be 90 degrees. Each of the non-slanted elongated holes 402A-C may have a top opening 422A on the top surface of the ion trap 400 and/or a bottom opening 422B on the bottom surface of the ion trap 400. The width 418 of the non-slanted elongated holes 402A-C may be between about 0.1 millimeter and 5 millimeters. The height 420 of the non-slanted elongated holes 402A-C may be between 5 millimeters to about 40 millimeters. The sum of the interior surface areas 414 of the elongated holes 402 may be lower than the sum of all the interior surface areas 214 of the holes 202 or the sum of the interior surface areas 314 of the slanted holes 302.

The non-slanted elongated holes 402A-C, similar to the holes 202 of the ion trap 200, may not trap all ions, and some of the ions may exit via the bottom opening 422B on the bottom surface of the ion trap 400. Therefore, a ion trap 400 with slanted elongated holes, such as the slanted elongated holes 402D, 402E, 402F as illustrated in FIG. 4C, may be preferred. The slanted elongated holes 402D-F may have a higher efficiency in trapping ions when compared to the non-slanted elongated holes 402A-C in FIG. 4B. Referring back to FIG. 4C, the interior surfaces 424 of the slanted elongated holes 402D-F may be slanted (e.g., not perpendicular) to the top surface of the ion trap 400 or the bottom surface of the ion trap 400. For example, the interior surfaces 424 of the slanted elongated holes 402D-F may create an angle 404 in a range of 45 to 89 degrees with the top surface or the bottom surface of the ion trap 400. In some examples, the angle 404 may be in the range of 70 to 85 degrees.

Each of the slanted elongated holes 402D-F may have a top opening 432A on the top surface of the ion trap 400 and/or a bottom opening 432B on the bottom surface of the ion trap 400. The width 428 of the top opening 432A and the bottom opening 432B may be between about 0.1 millimeter to about 5 millimeters. The slanted height 430 of the slanted elongated holes 402D-F may be between 5 millimeters to about 40 millimeters.

The slanted elongated holes 402D-F may let any radical species flowing toward the substrate (e.g., substrate 110) pass through the ion trap 400 by allowing the radicals to enter via the top openings 432A on the top surface of the ion trap 400 and exiting via the bottom openings 432B on the bottom surface of the ion trap 400. However, the slanted interior surface 424 may trap ions flowing towards the substrate, as the ions may collide with the slanted interior surface 424 and/or get absorbed by the slanted interior surface 424. The sum of the interior surface areas 424 of the slanted elongated holes 402D-F may be lower than the sum of all the interior surface areas 214 of the holes 202 or the sum of the interior surface areas 314 of the slanted holes 302, and therefore, the slanted elongated holes 402D-F may allow less radical recombination inside the slanted elongated holes 402D-F.

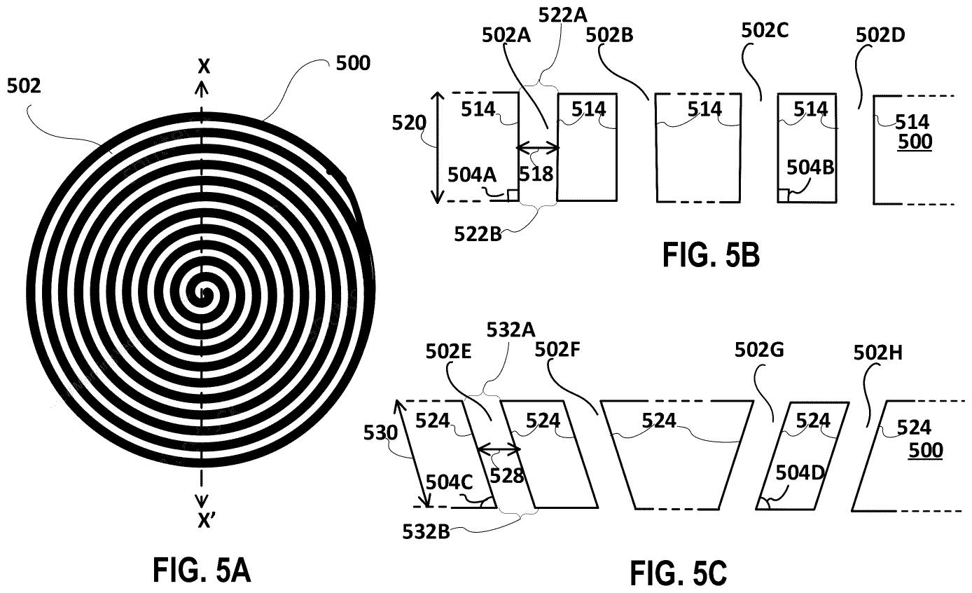

FIG. 5A illustrates another example ion trap 500 with an elongated hole 502 shaped like a spiral (e.g., the white portion within the black ion trap). The spiral elongated hole 502 may be non-slanted or slanted. For example, FIG. 5B illustrates a cross-sectional view of the ion trap 500 with a non-slanted spiral elongated hole with portions 502A, 502B, 502C, 502D along the x-x′ axis. The interior surfaces 514 of the portions 502A-D may be perpendicular to the top surface of the ion trap 500 or the bottom surface of the ion trap 500. The angles 504A and 504B between the interior surfaces 514 and the top or bottom surface may be 90 degrees. Each of the portions 502A-D may have a top opening 522A on the top surface of the ion trap 500 and/or a bottom opening 522B on the bottom surface of the ion trap 500. The width 518 of the portions 502A-D may be between about 0.1 millimeter and 5 millimeters. The height 520 of the portions 502A-D may be between 5 millimeters to about 40 millimeters. The sum of the interior surface area 514 of the non-slanted spiral elongated hole may be lower than the sum of all the interior surface areas 214 of the holes 202 or the sum of the interior surface areas 314 of the slanted holes 302.

A non-slanted spiral elongated hole, similar to the holes 202 of the ion trap 200, may not trap all ions, and some of the ions may exit via the bottom opening 522B on the bottom surface of the ion trap 500. Therefore, a ion trap 500 with a slanted spiral elongated hole may be preferred. For example, FIG. 5C illustrates a cross-sectional view of the ion trap 500 with a slanted spiral elongated hole with portions 502E, 502F, 502G, 502H along the x-x′ axis. The portions 502E-H may have a higher efficiency in trapping ions when compared to the portions 502A-D in FIG. 5B. Referring back to FIG. 5C, the interior surfaces 524 of the portions 502E-H may be slanted (e.g., not perpendicular) to the top surface of the ion trap 500 or the bottom surface of the ion trap 500. For example, the interior surfaces 524 of the portions 502E-H may create angles 504C and 504D in a range of 45 to 89 degrees with the top surface or the bottom surface of the ion trap. In some examples, the angles 504C and 504D may be in a range of 70 to 85 degrees with the top surface or the bottom surface of the ion trap

Each of the portions 502E-H may have a top opening 532A on the top surface of the ion trap 500 and/or a bottom opening 532B on the bottom surface of the ion trap 500. The width 528 of the portions 502E-H may be between about 0.1 millimeter to about 5 millimeters. The slanted height 530 of the slanted spiral elongated hole may be between 5 millimeters to about 40 millimeters.

The portions 502E-H may let any radical species flowing toward the substrate (e.g., substrate 110) pass through the ion trap 500 by allowing the radicals to enter via the top openings 532A on the top surface of the ion trap 500 and exiting via the bottom openings 532B on the bottom surface of the ion trap 500. However, the slanted interior surface 524 may trap ions flowing towards the substrate, as the ions may collide with the slanted interior surface 524 and/or get absorbed by the slanted interior surface 524. The sum of the interior surface area 524 of the slanted spiral elongated hole may be lower than the sum of all the interior surface areas 214 of the holes 202 or the sum of the interior surface areas 314 of the slanted holes 302, and therefore, having a ion trap 500 with the slanted spiral elongated hole may result in less radical recombination than a ion trap 500 with non-slanted spiral elongated hole.

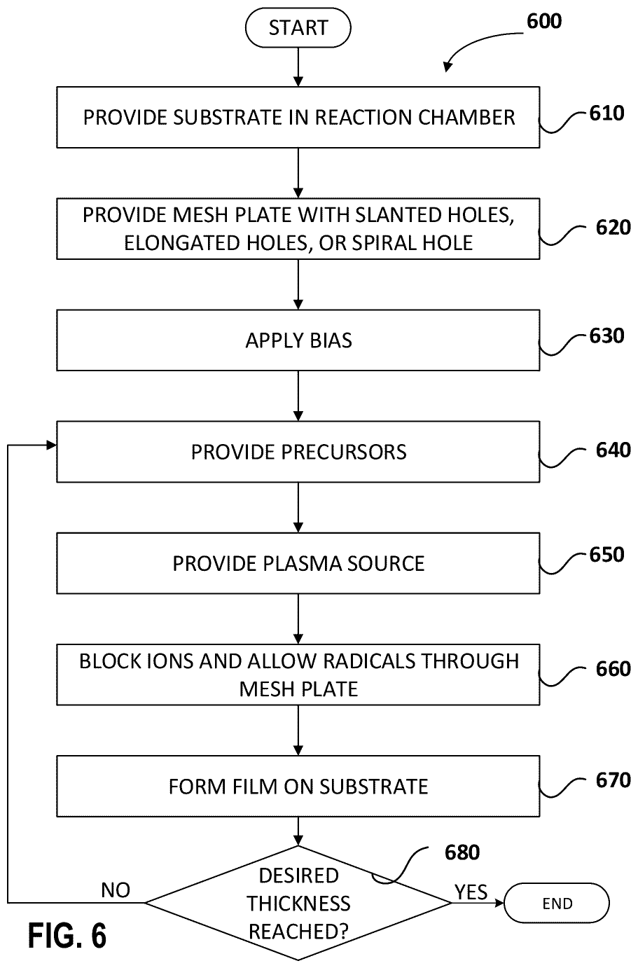

An aspect of the present disclosure is the method of depositing a film on the surface of a substrate that is contained in a reaction chamber using RE-ALD. FIG. 6 is a process flow diagram 600 of an embodiment of the disclosure. The RE-ALD process may comprise a vapor deposition process in which deposition cycles, typically a plurality of consecutive deposition cycles, are conducted in a reactor system. Generally, for RE-ALD processes, during each cycle, a precursor and a plasma may be introduced into a reaction chamber to form radicals, which may be chemisorbed onto a deposition surface (e.g., a substrate surface that can include a previously deposited material from a previous RE-ALD cycle or other material) and forming about a monolayer or sub-monolayer of material that does not readily react with additional radicals (i.e., a self-limiting reaction). Thereafter, a reactant (e.g., another precursor with plasma or just another precursor) may subsequently be introduced into the process chamber for use in converting the chemisorbed precursor to the desired material on the deposition surface. Purging steps may be utilized during one or more cycles, e.g., during each step of each cycle, to remove any excess precursor from the process chamber and/or remove any excess reactant, radicals, and/or reaction byproducts from the reaction chamber. As used herein, the term “pulse” may refer to a procedure in which a reactive precursor or reactant is provided to a reaction chamber, for example in between two purges, between a purge and another pulse, or between two pulses. It shall be understood that a pulse can be effected either in time or in space, or both. As used herein, the term “purge” may refer to a procedure in which an inert or substantially inert gas is provided to a reaction chamber in between two pulses of gasses that react with each other. For example, a purge, e.g. using a noble gas, may be provided between a precursor pulse and a reactant pulse, thus avoiding or at least minimizing gas phase interactions between the precursor and the reactant. It shall be understood that a purge can be effected either in time or in space, or both.

Referring back to FIG. 6, at step 610, a substrate (e.g., substrate 110) may be provided inside the reaction chamber of a reactor chamber (e.g., reaction chamber 100) of a reactor system (e.g., the reactor system 150). The substrate may be supported by a susceptor (e.g., susceptor 111). At step 620, a ion trap (e.g., the ion trap 109) may be provided inside the reactor chamber. The ion trap may be the ion trap 300 with slanted holes 302, the ion trap 400 with the non-slanted elongated holes 402A-C or the slanted elongated holes 402D-F, or the ion trap 500 with non-slanted spiral holes (e.g., with portions 502A-D) or slanted spiral holes (e.g., with portions 502E-H). The ion trap may be disposed above the substrate and below a precursor distribution system (e.g., the precursor distribution system 107). The ion trap may be connected to a ground connection.

Step 610 may be optional. At step 630, a bias may be applied between the susceptor (e.g., the susceptor 111) or an ion trap (e.g., the ion trap 109) of the reaction system and the precursor distribution system of the reactor system. The bias may enable ions and radicals to accelerate downward toward the substrate or the susceptor of the reactor system.

At step 640, a deposition cycle may be initiated where one or more precursors (e.g., precursors from the first precursor source 102, the second precursor source 103, the third precursor source 104, and/or the fourth precursor source 105) may be provided into the reaction chamber. The precursors may flow through the precursor distribution system that may be positioned directly above the ion trap. Other gases may also be provided (e.g., other precursors or reactive gasses, carrier, dilutant, process, feed, carrier gas, and/or purging gasses).

At step 650, a plasma source may be provided to partially break down at least a portion of a provided precursor to form activated radicals and ions. In the methods disclosed herein, a plasma may be formed between the ion trap and the precursor distribution system, and may be used to partially break down at least a portion of the provided precursors of step 640 to produce radicals (e.g., radicalized precursor) and ions. The radicals may be more reactive than the precursor from which it is derived, and these more reactive radicals may increase the rate of the chemisorption on the substrate surface. In this context, the term “break down” refers to the process or effect of dissociating, fragmenting, or decomposing a chemical entity (in this case, the precursor) into fragments, whereas “partial breakdown” means that the precursor is broken down but at least a portion of the molecular structure of the precursor remains substantially intact in the resulting radicalized precursor. Additionally, or alternatively, “partial breakdown” means that the precursor is broken down, but not to the extent that bimolecular and/or non-self-limited type adsorption occurs on the substrate surface; rather, the radicalized precursor chemisorbs on the substrate surface via a self-limited process. The plasma may be produced by vapor-phase ionization of a precursor using a radio frequency (RF) (e.g., 13.56 MHz or 27 MHZ) power source (e.g., the RF power source 113). Typically, the RF power for generating the plasma is maintained at about 300 W or less, typically at about 200 W or less, or more typically at about 100 W or less.

At step 660, the ion trap may allow radicals of step 650 to pass through the ion trap but may block ions by passing through the ion trap. A more efficient ion blocking may be achieved by using ion traps with slanted holes (e.g., the ion trap 300 with slanted holes 302, the ion trap 400 with slanted elongated holes 402D-F, or the ion trap 500 with a slanted spiral hole (e.g., with portions 502E-H)).

At step 670, the radicals of step 650 may contact the subtract to form a thin film of material on the substrate. The method wherein the substrate is contacted with the radicals may constitute one deposition cycle. In some examples, the method of depositing a thin film on a substrate may comprise repeating the deposition cycle one or more times. For example, the method 600 may continue with decision gate 680 which determines if the method 600 continues or exits. The decision gate 680 may be determined based on the thickness of the film deposited, for example, if the thickness of the film is insufficient, then the method 600 may return to step 640 and the steps of providing precursors and the steps of providing plasma sources may be repeated one or more times. Before returning to step 640, in some examples, the reaction chamber may be purged with one or more pursing gasses (e.g., inert gasses). In other examples, purging may be skipped. Purging the reaction chamber may remove any excess precursor from the process chamber and/or remove any excess reactant, radicals, ions, and/or reaction byproducts from the reaction chamber.

Once the film has been deposited to a desired thickness the method may exit. The film may be subjected to additional processes to form a device structure. The various steps shown in FIG. 6 may be repeated one or more times to grow a film of a desired thickness on the substrate surface. For example, in some embodiments, the method comprises repeating steps 640, 650, 660, and 670 one or more times to form a film of a desired thickness on the substrate surface. The number of repetitions of the deposition cycle (e.g., each cycle comprising steps 640, 650, 660, and 670) may depend on the growth per-cycle (GPC) rate of the deposited material and the desired thickness of the film. The methods according to the current disclosure may be performed by maintaining the substrate temperature from about 40° C. to about 600° C.

Although exemplary embodiments of the present disclosure are set forth herein, it should be appreciated that the disclosure is not so limited. For example, although reactor systems are described in connection with various specific configurations, the disclosure is not necessarily limited to these examples. Various modifications, variations, and enhancements of the system and method set forth herein may be made without departing from the spirit and scope of the present disclosure.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A reaction chamber, comprising:
a susceptor configured to support a substrate;
a precursor distribution system positioned above the susceptor and configured to provide one or more precursors into the reaction chamber;
a radio frequency (RF) power source configured to supply RF power for generating, in the reaction chamber, ions and radicals from the one or more precursors; and
an ion trap positioned between the susceptor and the precursor distribution system and comprising at least one hole, wherein the at least one hole comprises an interior surface that is:
slanted relative to a top surface or a bottom surface of the ion trap, and
configured to prevent the ions from passing through the ion trap and contacting the substrate.

2. The reaction chamber of claim 1, wherein the interior surface creates an angle in a range of 70 to 85 degrees with the top surface or the bottom surface of the ion trap.

3. The reaction chamber of claim 1, wherein the at least one hole comprises an opening on the top surface or the bottom surface of the ion trap; and
wherein the opening comprises a circular shape with a diameter in a range of 0.1 to 5 millimeters.

4. The reaction chamber of claim 1, wherein the at least one hole is shaped as an oblique cylinder.

5. The reaction chamber of claim 4, wherein the oblique cylinder comprises an aspect ratio in a range of 1 to 400.

6. The reaction chamber of claim 1, wherein the at least one hole comprises an opening on the top surface or the bottom surface of the ion trap; and
wherein the opening comprises a circular shape, a square shape, a rectangular shape, or a parallelogram shape.

7. The reaction chamber of claim 1, wherein the at least one hole comprises an opening on the top surface or the bottom surface of the ion trap; and
wherein the opening comprises a rectangular shape with a width in a range of 0.1 to 5 millimeters.

8. The reaction chamber of claim 7, wherein the ion trap comprises a plurality of holes with interior surfaces slanted relative to the top surface or the bottom surface of the ion trap; and
wherein the plurality of holes are parallel to each other.

9. The reaction chamber of claim 1, wherein the at least one hole comprises an opening on the top surface or the bottom surface of the ion trap; and
wherein the opening comprises a spiral shape with a width in a range of 0.1 to 5 millimeters.

10. The reaction chamber of claim 1, wherein the ion trap has a thickness in a range of 5 to 40 millimeters.

11. The reaction chamber of claim 1, wherein the at least one hole is configured to allow the radicals to pass through the ion trap.

12. The reaction chamber of claim 1, further comprising:
a controller,
wherein the RF power source is electrically connected to at least one of the susceptor and the precursor distribution system; and
wherein the controller is configured to enable the ions to move vertically toward the susceptor by activating the power source to apply a voltage bias to the at least one of the susceptor and the precursor distribution system.

13. The reaction chamber of claim 1, wherein the ion trap is connected to a ground connection.

14. An ion trap of a reaction chamber comprising:
a plurality of holes,
wherein an interior surface, of each of the plurality of holes, is slanted relative to a top surface or a bottom surface of the ion trap; and
wherein the plurality of holes are configured to block ions from passing through the ion trap and allow radicals to pass through the ion trap.

15. The ion trap of claim 14, wherein the interior surface, of each of the plurality of holes, creates an angle in a range of 70 to 85 degrees with the top surface or the bottom surface of the ion trap.

16. The ion trap of claim 14, wherein each of the plurality of holes comprises a shape of an oblique cylinder with a diameter in a range of 0.1 to 5 millimeters and an aspect ratio in a range of 1 to 400.

17. The ion trap of claim 14, wherein each of the plurality of holes comprises a rectangular shape with a width in a range of 0.1 to 5 millimeters.

18. The ion trap of claim 17, wherein the plurality of holes are parallel to each other.

19. The ion trap of claim 14, wherein the ion trap has a thickness in a range of 5 to 40 millimeters.

20. An ion trap of a reaction chamber comprising:
a hole comprising a spiral shape,
wherein an interior surface of the hole is slanted relative to a top surface or a bottom surface of the ion trap; and
wherein the hole is configured to block ions from passing through the ion trap and allow radicals to pass through the ion trap.
